(19) United States
(12) Patent Application Publication
(10) Pub. No.: US 2026/0246428 A1
(43) Pub. Date: Aug. 20, 2026

(54) PHASE COMPENSATION CIRCUIT

(71) Applicant: SKYWORKS SOLUTIONS, INC., Irvine, CA (US)

(72) Inventors: Houdong Yin, Cypress, CA (US); Kyung-Wan Yu, Irvine, CA (US)

(21) Appl. No.: 19/180,975

(22) Filed: Apr. 16, 2025

Related U.S. Application Data
(60) Provisional application No. 63/635,084, filed on Apr. 17, 2024.

(51) Int. Cl. H03F 1/02; H03F 3/24; H03H 7/18

(52) U.S. Cl. CPC H03F 1/0288; H03F 3/245; H03H 7/18; H03F 2200/451

(57) ABSTRACT

A device may include a carrier path including a first carrier amplifier. A device may include a peaking path including a first peaking amplifier. A device may include a phase shifter comprising a first reactance component, the phase shifter coupled to an input of the first carrier amplifier and configured to shift a phase of the carrier path.

### CROSS-REFERENCE TO RELATED APPLICATION(S)

This application claims priority to U.S. Provisional Application No. 63/635,084 filed Apr. 17, 2024, entitled PHASE COMPENSATION CIRCUIT, the disclosure of which is hereby expressly incorporated by reference herein in its entirety.

### BACKGROUND

The present disclosure generally relates to the field of electronics, and more particularly, to radio-frequency (RF) modules and devices. RF signals can be amplified using power amplifier (PA) circuitry.

### SUMMARY

In accordance with a number of implementations, the present disclosure relates to a Doherty power amplifier including a carrier path including a first carrier amplifier; a peaking path including a first peaking amplifier; and a phase shifter including a first reactance component, the phase shifter coupled to an input of the first carrier amplifier and configured to shift a phase of the carrier path.

In some aspects, the carrier path further includes a second carrier amplifier and the peaking path further includes a second peaking amplifier. The Doherty power amplifier may further include an inter-stage matching network coupled between the first carrier amplifier and the second carrier amplifier.

The Doherty power amplifier may further include an input splitter, wherein the phase shifter is coupled between the input splitter and the first carrier amplifier.

In some aspects, the Doherty power amplifier further includes a transmission line coupled to an input of the input splitter. The Doherty power amplifier may further include a first matching network coupled between the first carrier amplifier and the phase shifter.

The phase shifter may further include a second reactance component. In some aspects, the phase shifter further includes a coupler coupled to the first reactance component and second reactance component.

In some aspects, the coupler is a hybrid coupler. The first reactance component and the second reactance component may be inductors. In some aspects, the first reactance component and the second reactance component are capacitors.

In accordance with some implantations, the present disclosure relates to a method of amplifying a radio-frequency signal including receiving a radio-frequency signal; splitting the radio-frequency signal between a carrier path and a peaking path via an input splitter, the carrier path including a first carrier amplifier and the peaking path including a first peaking amplifier; and shifting a phase of the radio-frequency signal at the carrier path via a phase shifter including a first reactance component, the phase shifter coupled to an input of the first carrier amplifier.

In some aspects, the carrier path further includes a second carrier amplifier and the peaking path further includes a second peaking amplifier. A transmission line may be coupled to an input of the input splitter.

The carrier path may further include a first matching network coupled between the first carrier amplifier and the phase shifter. In some aspects, the phase shifter further includes a second reactance component.

In some aspects, the phase shifter further includes a coupler coupled to the first reactance component and second reactance component. The coupler may be a hybrid coupler.

The first reactance component and the second reactance component may be inductors. In some aspects, the first reactance component and the second reactance component are capacitors.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 illustrates a wireless system or architecture having an amplification system.

FIG. 2 shows that the amplification system of FIG. 1 typically includes a radio-frequency (RF) amplifier assembly having one or more power amplifiers (PAs).

FIG. 3 illustrates an example power amplifier (e.g., Doherty power amplifier) in accordance with one or more examples.

FIG. 4 illustrates another example power amplifier (e.g., Doherty power amplifier) in accordance with one or more examples.

FIG. 5 illustrates an example phase shifter in accordance with one or more examples.

FIG. 6 illustrates an example phase shifter in accordance with one or more examples.

FIG. 7 shows that in some embodiments, some or all of Doherty power amplification systems described herein can be implemented in a module.

FIG. 8 depicts an example wireless device having one or more advantageous features described herein.

### DESCRIPTION

The headings provided herein, if any, are for convenience only and do not necessarily affect the scope or meaning of the claimed invention.

The present disclosure generally relates to the field of electronics, and more particularly, to radio-frequency (RF) modules and devices. RF signals can be amplified using power amplifier (PA) circuitry.

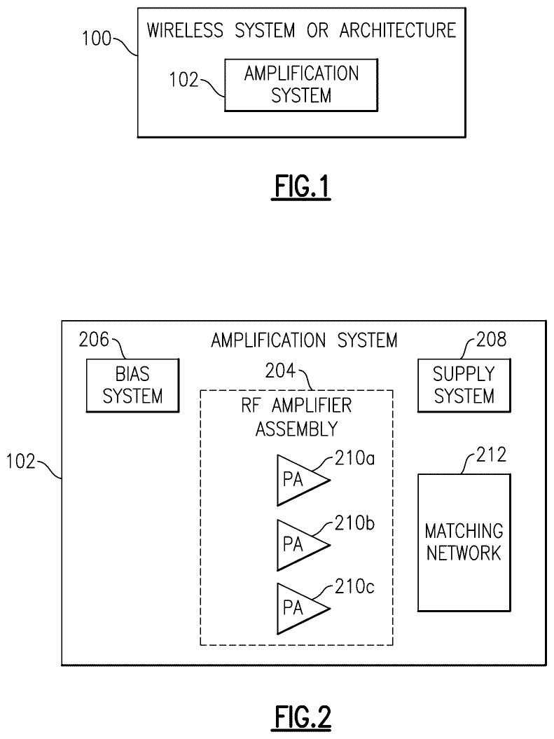

Referring to FIG. 1, one or more features of the present disclosure generally relate to a wireless system or architecture 100 having an amplification system 102. In some embodiments, the amplification system 102 can be implemented as one or more devices, and such device(s) can be utilized in the wireless system/architecture 100. In some embodiments, the wireless system/architecture 100 can be implemented in, for example, a portable wireless device. Examples of such a wireless device are described herein.

FIG. 2 shows that the amplification system 102 of FIG. 1 typically includes a radio-frequency (RF) amplifier assembly 204 having one or more power amplifiers (PAs). In the example of FIG. 2, three PAs 210a-210c are depicted as forming the RF amplifier assembly 204. It will be understood that other numbers of PA(s) can also be implemented. It will also be understood that one or more features of the present disclosure can also be implemented in RF amplifier assemblies having other types of RF amplifiers.

In some embodiments, the RF amplifier assembly 204 can be implemented on one or more semiconductor die, and such die can be included in a packaged module such as a power amplifier module (PAM) or a front-end module (FEM). Such a packaged module may be mounted on a circuit board associated with, for example, a portable wireless device.

The PAs (e.g., 210a-210c) in the amplification system 102 can be biased by a bias system 206. Further, supply voltages for the PAs are typically provided by a supply system 208. In some embodiments, either or both of the bias system 206 and the supply system 208 can be included in the foregoing packaged module having the RF amplifier assembly 204.

In some embodiments, the amplification system 102 can include a matching network 212. Such a matching network can be configured to provide input matching and/or output matching functionalities for the RF amplifier assembly 204.

In some examples, a PA can be configured as a Doherty PA. Such a Doherty PA can include amplifying transistors configured to provide carrier amplification and peaking amplification of an input RF signal (RF_in) to yield an amplified output RF signal (RF_out). The input RF signal can be split into the carrier portion and the peaking portion by a splitter. The amplified carrier and peaking signals can be combined to yield the output RF signal by a combiner. Doherty amplifiers may offer relatively improved efficiency compared to balanced amplifiers, in certain configurations, and may be particularly applicable in RF communication systems.

The phase difference between a carrier path and a a peak path of a Doherty amplifier can be in an approximately 0-90-degree range. To compensate phase difference, a transmission line (e.g., a 50 ohm transmission line) may be used to provide additional phase. At carrier amplifier and/or peak amplifier input, the transmission line may not affect input matching when the phase is adjusted. However, to achieve a relatively large phase offset (e.g., 30-90-degree), the transmission line may need to be exceptionally long. A long transmission line may not present a problem on board level design; however, the transmission line may be a problem on a radio-frequency integrated circuit (RFIC).

In some cases, bonding wire and/or extra transmission line may be used to compensate for phase difference. To adjust the phase, the bonding wire length and/or bonding wire location(s) may be changed, which may not be convenient on RFIC power amplifier module (PAM) design because of limited package size and the difficulty of implementing such lengths and/or positions of bonding wires.

A reflection-type phase shifter can comprise a 3 dB hybrid coupler and/or multiple (e.g., two) identical reactance components. The reactance components can comprise one or more inductors (e.g., two inductors) and/or one or more capacitors (e.g., two capacitors). By changing values of the inductor(s) or capacitor(s), a 0-360-degree phase change can be achieved. A 3 dB hybrid coupler can be implemented on a relatively small integrated passive device (IPD) die and/or surface-mount technology (SMT) components. Phase can be adjusted effectively by adjusting and/or changing the reactance component(s).

FIG. 3 illustrates an example power amplifier 300 (e.g., Doherty power amplifier) in accordance with one or more examples. The amplifier 300 can comprise an input splitter 302, carrier amplifier 304, peak amplifier 306, and a combiner 308 (e.g., Doherty combiner). The carrier amplifier 304 may be biased at class AB mode and/or the peak amplifier 306 may be biased at class C mode. To achieve maximum combining power, the carrier amplifier 304 path and/or peak amplifier 306 path may be in phase at a maximum power level. The carrier amplifier 304 path and/or peak amplifier 306 path may comprise an input matching network (IMN) 310 and/or an output matching network (OMN) 315.

In some examples, the amplifier 300 may comprise a first phase shifter 326 and/or second phase shifter 327 configured to shift phase and/or provide phase to the amplifier 300. The first phase shifter 326 and/or second phase shifter 327 may comprise various components as described herein. In some examples, the first phase shifter 326 may be coupled between the input splitter 302 and the IMN 310 of the carrier path and/or the second phase shifter 327 may be coupled between the input splitter 302 and the IMN 310 of the peak path. The amplifier 300 may additionally comprise a transmission line 318 (e.g., 50 ohm transmission line) configured to provide additional phase to the amplifier 300.

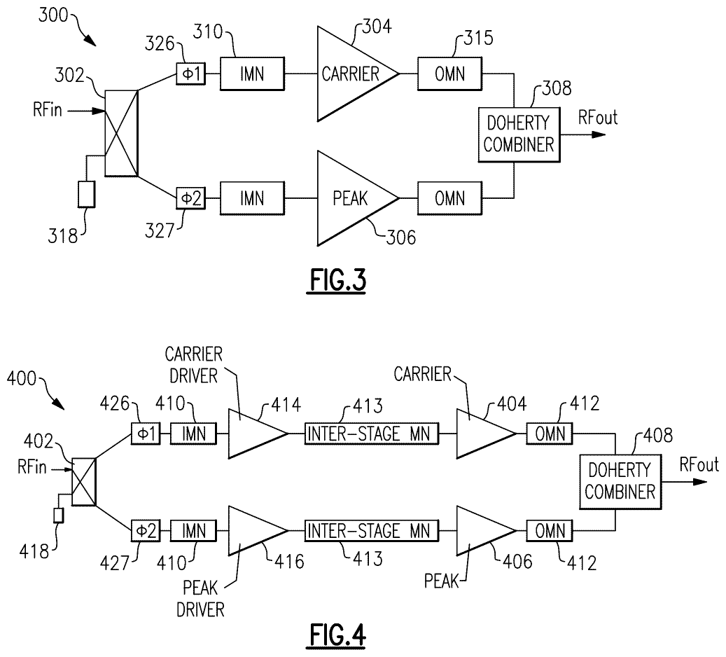

FIG. 4 illustrates another example power amplifier 400 (e.g., Doherty power amplifier) in accordance with one or more examples. The amplifier 400 can comprise an input splitter 402, carrier amplifier 404, peak amplifier 406, and a combiner 408 (e.g., Doherty combiner). The carrier amplifier 404 may be biased at class AB mode and/or the peak amplifier 406 may be biased at class C mode. To achieve maximum combining power, the carrier amplifier 404 path and/or peak amplifier 406 path may be in phase at a maximum power level. The carrier amplifier 404 path and/or peak amplifier 406 path may comprise an input matching network (IMN) 410 and/or an output matching network (OMN) 412.

The amplifier 400 may also comprise a carrier driver 414 and/or a peak driver 416. A first inter-stage matching network 413 may be disposed between the carrier driver 414 and the carrier amplifier 404 and/or a second inter-stage matching network 413 may be disposed between the peak driver 416 and the peak amplifier 406. The amplifier 400 may comprise a transmission line 418 (e.g., approximately 50 ohm transmission line) to provide additional phase difference between the carrier amplifier 404 path and the peak amplifier 406 path.

The amplifier 400 may comprise an asymmetrical Doherty amplifier wherein the carrier amplifier 404 and the peak amplifier 406 have different sizes. The carrier amplifier 404 and the peak amplifier 406 may have a phase difference which may be due, at least in part, to different in input matching and/or output matching of the carrier amplifier 404 path and/or peak amplifier 406 at least at maximum power levels. Thus, it may be advantageous to add additional phase at an input side of the carrier path and/or peak path.

In some examples, the amplifier 400 may comprise a two-stage cascade asymmetrical Doherty amplifier. The first inter-stage matching network 413 and the second inter-stage matching network 413 may be different and/or may be configured to create and/or increase a phase difference between the carrier amplifier 404 path and the peak amplifier 406 path. In this way, the first inter-stage matching network 413 and the second inter-stage matching network 413 may be configured to compensate phase difference at maximum power levels. In some examples, a first phase shifter 426 and/or a second phase shifter 427 may be placed at an input side of the carrier amplifier 404 path and/or the peak amplifier 406 path. The first phase shifter 426 and/or second phase shifter 427 may comprise various components as described herein.

The amplifier 400 may comprise a gallium nitride (GaN) PAM (e.g., a 16W GaN PAM having a frequency band of approximately 3.4-3.8 GHz) including a two-stage Doherty core PAM. In some examples, the carrier driver 414 may comprise one cell and/or the peak driver 416 may comprise two cells. The carrier amplifier 404 may comprise seven cells and/or the peak amplifier 406 may comprise twelve cells. The carrier amplifier 404 path and/or peak amplifier 406 path may be different at maximum power levels and/or a phase difference between the carrier amplifier 404 path and/or peak amplifier 406 path may be approximately 66-degrees. To compensate the phase difference, an extra 66-degree phase may be added to carrier amplifier 404 path.

To compensate phase difference (e.g., on a PAM), it may be advantageous to use a transmission line 418 (e.g., a 50 ohm transmission line) to adjust the phase. The transmission line 418 may be configured to adjust phase without affecting input matching. To achieve 66-degree phase at approximately 3.6 GHz, a transmission line 418 having a length of approximately 9350 μm may be required. However, such a transmission line 418 may be too long to fit it in a small package size. Even a folded transmission line 418 having a length of approximately 5000 μm may be too large to fit. A 50 ohm transmission line 418 may be difficult to adjust the phase on a multi-chip module (MCM).

FIG. 5 illustrates an example phase shifter 500 in accordance with one or more examples. To advantageously reduce size and/or increase effectiveness of the phase shifter 500, a power amplifier may advantageously comprise a reflection-type phase shifter 500 comprising a coupler 502 (e.g., 3 dB hybrid coupler) and two inductors 504 (e.g., reactance components and/or SMT devices). For example, a first inductor 504a may have a size of approximately 01005 or 008004 and/or a second inductor 504 b may also have a size of approximately 01005 or 008004. In some examples, two 27 nH inductors 504 may be required to achieve a 66-degree phase. However, any phase (at least within a 180-degree range) may be achievable by changing the inductance value of the inductors 504. The phase shifter 500 may be approximately 1900 μm in size, which may be relatively easy to fit it in a module.

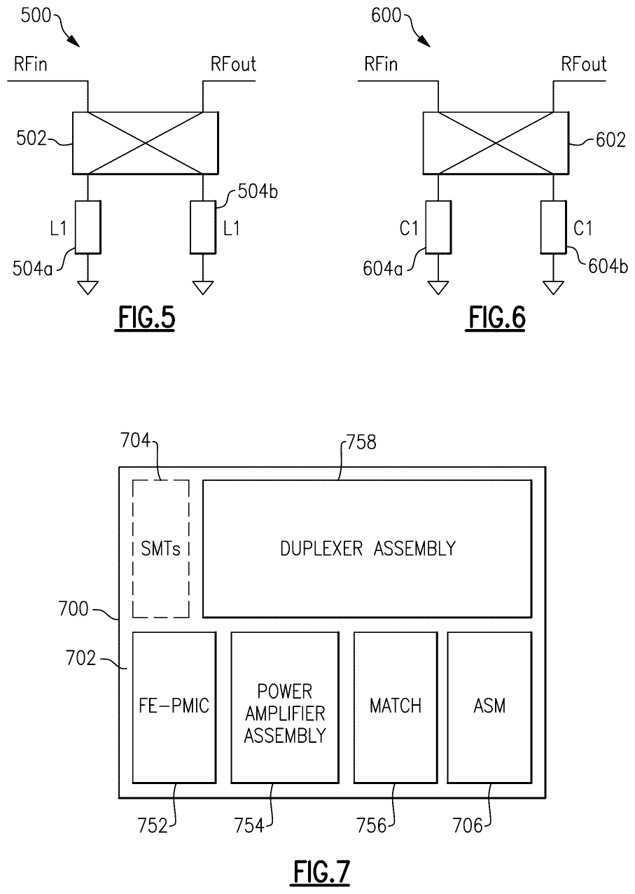

FIG. 6 illustrates an example phase shifter 600 in accordance with one or more examples. To advantageously reduce size and/or increase effectiveness of the phase shifter 600, a power amplifier may advantageously comprise a reflection-type phase shifter 600 comprising a coupler 602 (e.g., 3 dB hybrid coupler) and/or capacitors 604 (e.g., reactance components and/or SMT devices). In some examples, a first capacitor 604a and/or a second capacitor 604b may achieve a 66-degree phase. However, any phase (at least within a −180 to 0-degree range) may be achievable by changing the capacitance value(s) of the capacitors 604. The phase shifter 600 may be approximately 1900 μm in size, which may be relatively easy to fit it in a module.

FIG. 7 shows that in some embodiments, some or all of Doherty power amplification systems described herein can be implemented in a module. Such a module can be, for example, a front-end module (FEM). In the example of FIG. 7, a module 700 can include a packaging substrate 702, and a number of components can be mounted on such a packaging substrate. For example, an FE-PMIC component 752, a power amplifier assembly 754, a match component 756, and a duplexer assembly 758 can be mounted and/or implemented on and/or within the packaging substrate 702. Other components such as a number of SMT devices 704 and an antenna switch module (ASM) 706 can also be mounted on the packaging substrate 702. Although all of the various components are depicted as being laid out on the packaging substrate 702, it will be understood that some component(s) can be implemented over other component(s).

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

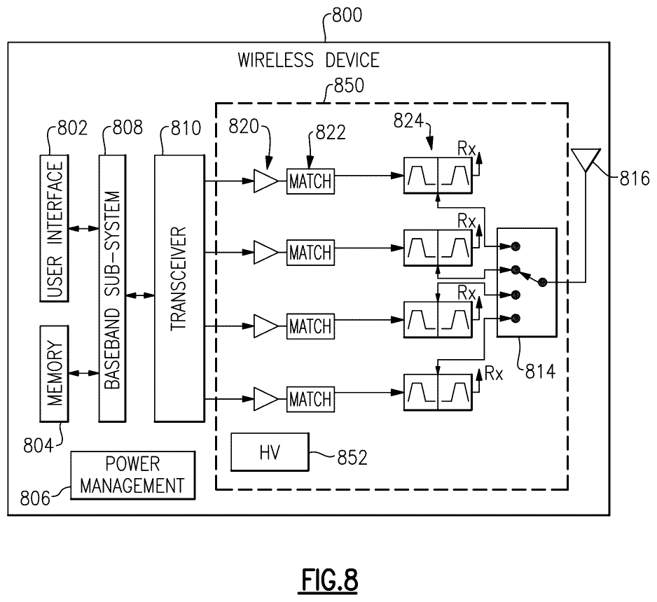

FIG. 8 depicts an example wireless device 800 having one or more advantageous features described herein. In the context of a module having one or more features as described herein, such a module can be generally depicted by a dashed box 850, and can be implemented as, for example, a front-end module (FEM).

Referring to FIG. 8, power amplifiers (PAs) 820 can receive their respective RF signals from a transceiver 810 that can be configured and operated in known manners to generate RF signals to be amplified and transmitted, and to process received signals. The transceiver 810 is shown to interact with a baseband sub-system 808 that is configured to provide conversion between data and/or voice signals suitable for a user and RF signals suitable for the transceiver 810. The transceiver 810 can also be in communication with a power management component 806 that is configured to manage power for the operation of the wireless device 800. Such power management can also control operations of the baseband sub-system 808 and the module 850.

The baseband sub-system 808 is shown to be connected to a user interface 802 to facilitate various input and output of voice and/or data provided to and received from the user. The baseband sub-system 808 can also be connected to a memory 804 that is configured to store data and/or instructions to facilitate the operation of the wireless device, and/or to provide storage of information for the user.

In the example wireless device 800, outputs of the PAs 820 are shown to be matched (via respective match circuits 822) and routed to their respective duplexers 824. In some embodiments, the match circuit 822 can include matching circuits. The outputs of the PAs 820 can be routed to their respective duplexers 824 without impedance transformation when the PAs 820 are operated with HV supply 852. Such amplified and filtered signals can be routed to an antenna 816 through an antenna switch 814 for transmission. In some embodiments, the duplexers 824 can allow transmit and receive operations to be performed simultaneously using a common antenna (e.g., 816). In FIG. 8, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

As described herein, one or more features of the present disclosure can provide a number of advantages when implemented in systems such as those involving the wireless device of FIG. 8. For example, significant current drain reduction can be achieved through an elimination or reduction of output loss. In another example, lower bill of materials count can be realized for the power amplification system and/or the wireless device. In yet another example, independent optimization or desired configuration of each supported frequency band can be achieved due to, for example, separate PAs for their respective frequency bands. In yet another example, optimization or desired configuration of maximum or increased output power can be achieved through, for example, a boost supply voltage system. In yet another example, a number of different battery technologies can be utilized, since maximum or increased power is not necessarily limited by battery voltage.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number, respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A Doherty power amplifier comprising:
a carrier path including a first carrier amplifier;
a peaking path including a first peaking amplifier; and
a phase shifter comprising a first reactance component, the phase shifter coupled to an input of the first carrier amplifier and configured to shift a phase of the carrier path.

2. The Doherty power amplifier of claim 1 wherein the carrier path further comprises a second carrier amplifier and the peaking path further comprises a second peaking amplifier.

3. The Doherty power amplifier of claim 2 further comprising an inter-stage matching network coupled between the first carrier amplifier and the second carrier amplifier.

4. The Doherty power amplifier of claim 1 further comprising an input splitter, wherein the phase shifter is coupled between the input splitter and the first carrier amplifier.

5. The Doherty power amplifier of claim 4 further comprising a transmission line coupled to an input of the input splitter.

6. The Doherty power amplifier of claim 1 further comprising a first matching network coupled between the first carrier amplifier and the phase shifter.

7. The Doherty power amplifier of claim 1 wherein the phase shifter further comprises a second reactance component.

8. The Doherty power amplifier of claim 7 wherein the phase shifter further comprises a coupler coupled to the first reactance component and second reactance component.

9. The Doherty power amplifier of claim 8 wherein the coupler is a hybrid coupler.

10. The Doherty power amplifier of claim 8 wherein the first reactance component and the second reactance component are inductors.

11. The Doherty power amplifier of claim 8 wherein the first reactance component and the second reactance component are capacitors.

12. A method of amplifying a radio-frequency signal comprising:
receiving a radio-frequency signal;
splitting the radio-frequency signal between a carrier path and a peaking path via an input splitter, the carrier path comprising a first carrier amplifier and the peaking path comprising a first peaking amplifier; and
shifting a phase of the radio-frequency signal at the carrier path via a phase shifter comprising a first reactance component, the phase shifter coupled to an input of the first carrier amplifier.

13. The method of claim 12 wherein the carrier path further comprises a second carrier amplifier and the peaking path further comprises a second peaking amplifier.

14. The method of claim 12 wherein a transmission line is coupled to an input of the input splitter.

15. The method of claim 12 wherein the carrier path further comprises a first matching network coupled between the first carrier amplifier and the phase shifter.

16. The method of claim 12 wherein the phase shifter further comprises a second reactance component.

17. The method of claim 16 wherein the phase shifter further comprises a coupler coupled to the first reactance component and second reactance component.

18. The method of claim 17 wherein the coupler is a hybrid coupler.

19. The method of claim 17 wherein the first reactance component and the second reactance component are inductors.

20. The method of claim 17 wherein the first reactance component and the second reactance component are capacitors.
